(19) United States
(12) Patent Application Publication
(10) Pub. No.: US 2024/0268099 A1
(43) Pub. Date: Aug. 8, 2024

(54) SEMICONDUCTOR STRUCTURE AND MANUFACTURING METHOD THEREOF

(71) Applicant: NANYA TECHNOLOGY CORPORATION, New Taipei City (TW)

(72) Inventor: Chun-Heng WU, Taoyuan City (TW)

(21) Appl. No.: 18/164,634

(22) Filed: Feb. 6, 2023

(51) Int. Cl. H10B 12/00; H01L 21/311; H01L 21/762

(52) U.S. Cl. CPC H10B 12/482; H01L 21/31116; H01L 21/31144; H01L 21/762

(57) ABSTRACT

A semiconductor structure includes a semiconductor substrate, an isolation structure, and a conductive structure. The isolation structure is located on the semiconductor substrate. The isolation structure has a first top surface, a second top surface lower than the first top surface, and a lateral surface adjoining the first top surface and the second top surface. The conductive structure has a trench. The trench extends to the second top surface and the lateral surface of the isolation structure. The conductive structure surrounds the isolation structure. The conductive structure is in contact with the first top surface of the isolation structure. A sidewall of a lower portion of the conductive structure is in contact with the isolation structure and extends beyond the second top surface of the isolation structure.

### BACKGROUND

### Field of Invention

The present disclosure relates to a semiconductor structure and a manufacturing method of the semiconductor structure.

### Description of Related Art

Generally speaking, a conductive electrode is located on a storage node contact (SNC) structure in a dynamic random access memory (DRAM) device to be electrically connected with the SNC structure. During the fabrication process of the conductive electrode, first of all, a conductive layer is deposited on the SNC structures of the DRAM device. Subsequently, a plurality of trenches are formed in the conductive layer, which divide the conductive layer into conductive electrodes respectively in contact with the SNC structures.

Typically, the material of the conductive layer is tungsten. Hence, as the conductive layer is dry etched to form the trenches and the conductive electrodes, byproducts and polymers of tungsten are also produced in the trenches, which may induce shorting between the conductive electrodes.

### SUMMARY

One aspect of the present disclosure provides a semiconductor structure.

According to some embodiments of the present disclosure, a semiconductor structure includes a semiconductor substrate, an isolation structure, and a conductive structure. The isolation structure is located on the semiconductor substrate. The isolation structure has a first top surface, a second top surface lower than the first top surface, and a lateral surface adjoining the first top surface and the second top surface. The conductive structure has a trench. The trench extends to the second top surface and the lateral surface of the isolation structure. The conductive structure surrounds the isolation structure. The conductive structure is in contact with the first top surface of the isolation structure. A sidewall of a lower portion of the conductive structure is in contact with the isolation structure and extends beyond the second top surface of the isolation structure.

In some embodiments, the conductive structure further includes an upper portion located on the lower portion of the conductive structure and the first top surface of the isolation structure.

In some embodiments, a distance between the lateral surface of the isolation structure and the sidewall of the lower portion of the conductive structure is less than a width of the trench surrounded by the upper portion of the conductive structure.

In some embodiments, a sidewall of the upper portion of the conductive structure has a bottom concave surface adjoining the sidewall of the lower portion of the conductive structure.

In some embodiments, a sidewall of the upper portion of the conductive structure has a bottom concave surface extending to the lateral surface of the isolation structure.

In some embodiments, the semiconductor structure further includes a hard mask layer. The hard mask layer is located on the upper portion of the conductive structure.

In some embodiments, the sidewall of the upper portion of the conductive structure has a top concave surface adjoining a top surface of the upper portion of the conductive structure.

In some embodiments, the semiconductor structure further includes a hard mask layer. The hard mask layer is located on the upper portion of the conductive structure. The top concave surface of the sidewall of the upper portion of the conductive structure extends to a sidewall of the hard mask layer.

In some embodiments, the first top surface, the lateral surface, and the second top surface of the isolation structure define a stepped surface.

Another aspect of the present disclosure provides a manufacturing method of a semiconductor structure.

According to some embodiments of the present disclosure, a manufacturing method of a semiconductor structure includes forming an isolation structure, a conductive structure surrounding and covering the isolation structure, and a hard mask layer on a semiconductor substrate sequentially, wherein the hard mask layer has an opening to expose the conductive structure; removing the exposed conductive structure to form a trench, such that a sidewall of an upper portion of the conductive structure has a bottom concave surface; forming a liner layer on the isolation structure, the sidewall of the upper portion of the conductive structure, and a sidewall and a top surface of the hard mask layer; removing a bottom portion of the liner layer to expose the isolation structure; removing the exposed isolation structure, such that the isolation structure has a first top surface covered by the conductive structure, a second top surface lower than the first top surface, and a lateral surface adjoining the first top surface and the second top surface, and the trench extends to the second top surface and the lateral surface of the isolation structure; and removing the liner layer to expose the sidewall of the upper portion of the conductive structure, and the sidewall and the top surface of the hard mask layer.

In some embodiments, removing the bottom portion of the liner layer to expose the isolation structure further includes removing a byproduct layer on the isolation structure.

In some embodiments, removing the exposed isolation structure is performed such that a sidewall of a lower portion of the conductive structure extends beyond the second top surface of the isolation structure.

In some embodiments, removing the exposed isolation structure is performed by reactive-ion etching having selectivity between the isolation structure and each of the liner layer and the conductive structure.

In some embodiments, forming the liner layer on the isolation structure, the sidewall of the upper portion of the conductive structure, and the sidewall and the top surface of the hard mask layer is performed by atomic layer deposition.

Yet another aspect of the present disclosure provides a manufacturing method of a semiconductor structure.

According to some embodiments of the present disclosure, a manufacturing method of a semiconductor structure includes forming an isolation structure, a conductive structure surrounding and covering the isolation structure, and a hard mask layer on a semiconductor substrate sequentially, wherein the hard mask layer has an opening to expose the conductive structure; forming a liner layer on a sidewall and a top surface of the hard mask layer and the exposed conductive structure; removing a bottom portion of the liner layer to expose the conductive structure; removing the conductive structure not covered by the hard mask layer and the liner layer to form a trench and expose the isolation structure, such that a sidewall of an upper portion of the conductive structure has a bottom concave surface; removing the exposed isolation structure, such that the isolation structure has a first top surface covered by the conductive structure, a second top surface lower than the first top surface, and a lateral surface adjoining the first top surface and the second top surface, and the trench extends to the second top surface and the lateral surface of the isolation structure; and removing the liner layer to expose the sidewall and the top surface of the hard mask layer.

In some embodiments, forming the isolation structure, the conductive structure surrounding and covering the isolation structure, and the hard mask layer on the semiconductor substrate subsequently further includes removing the exposed conductive structure, such that the sidewall of the upper portion of the conductive structure further has a top concave surface extending to the sidewall of the hard mask layer.

In some embodiments, forming the liner layer on the sidewall and the top surface of the hard mask layer and the exposed conductive structure is performed such that the liner layer is in contact with the top concave surface of the sidewall of the upper portion of the conductive structure.

In some embodiments, removing the exposed isolation structure is performed such that a sidewall of a lower portion of the conductive structure extends beyond the second top surface of the isolation structure.

In some embodiments, removing the conductive structure not covered by the hard mask layer and the liner layer to form the trench and expose the isolation structure is performed by reactive-ion etching having selectivity between the conductive structure and each of the liner layer and the isolation structure.

In some embodiments, forming the liner layer on the sidewall and the top surface of the hard mask layer and the exposed conductive structure is performed by atomic layer deposition.

In the aforementioned embodiments of the present disclosure, since the sidewall of the lower portion of the conductive structure of the semiconductor structure extends beyond the second top surface of the isolation structure, the cross-sectional area of the conductive structure adjacent to the first top surface of the isolation structure is increased compared with a traditional structure. As a result, the conductive structure is stronger, and the resistance of the conductive structure is reduced. The semiconductor structure may be applied in a dynamic random access memory (DRAM) device, and the conductive structure can act as an electrode of storage node contact (SNC) structure to reduce the resistance thereof. Furthermore, in the manufacturing method of the semiconductor structure, by forming the liner layer on the sidewall of the upper portion of the conductive structure and removing the bottom portion of the liner layer, byproducts and polymers of the conductive structure produced by a dry etching process can be prevented. Therefore, the manufacturing method of the semiconductor structure may be applied to fabricate DRAM device to avoid the shorting between electrodes of storage node contact (SNC) structures induced by the byproducts and the polymers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure according to one embodiment of the present disclosure.

FIGS. 2 to 6 are cross-sectional views at intermediate stages of the manufacturing method of the semiconductor structure of FIG. 1.

FIG. 7 is a cross-sectional view of a semiconductor structure according to one embodiment of the present disclosure.

FIGS. 8 to 11 are cross-sectional views at intermediate stages of the manufacturing method of the semiconductor structure of FIG. 7.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

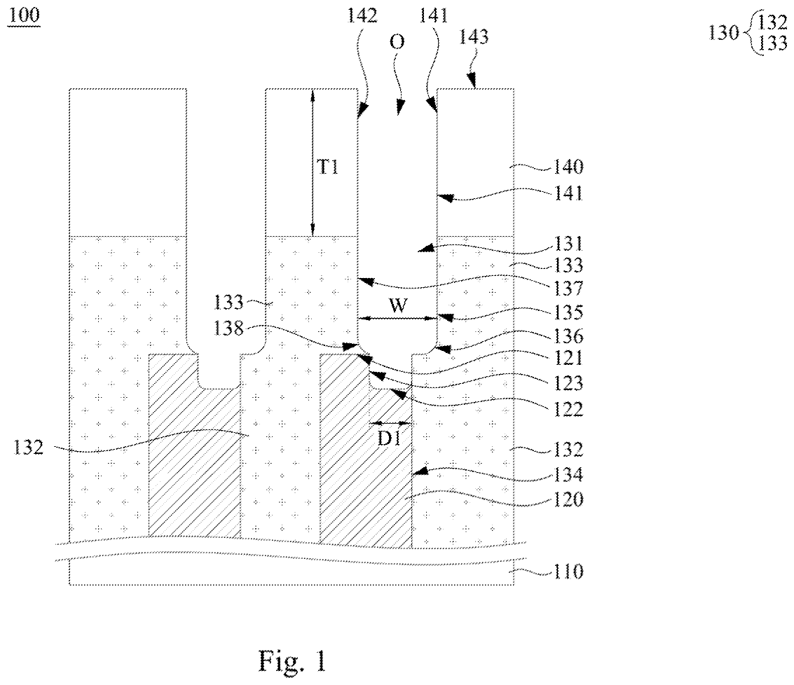

FIG. 1 is a cross-sectional view of a semiconductor structure 100 according to one embodiment of the present disclosure. As shown in FIG. 1, the semiconductor structure 100 includes a semiconductor substrate 110, an isolation structure 120, and a conductive structure 130. The isolation structure 120 is located on the semiconductor substrate 110. The isolation structure 120 has a first top surface 121, a second top surface 122 lower than the first top surface 121, and a lateral surface 123 adjoining the first top surface 121 and the second top surface 122. The conductive structure 130 has a trench 131. The trench 131 extends to the second top surface 122 and the lateral surface 123 of the isolation structure 120. Hence, the trench 131 divides the conductive structure 130 into two portions electrically insulated with each other. The conductive structure 130 surrounds the isolation structure 120. The conductive structure 130 is in contact with the first top surface 121 of the isolation structure 120. A sidewall 134 of a lower portion 132 of the conductive structure 130 is in contact with the isolation structure 120 and extends beyond the second top surface 122 of the isolation structure 120.

In some embodiments, the semiconductor structure 100 is applied in a dynamic random access memory (DRAM) device. The semiconductor substrate 110 may be a memory structure of the DRAM device. The isolation structure 120 may be in contact with a bit line (BL) structure of the DRAM device. The conductive structure 130 can act as an electrode of a storage node contact (SNC) structure of the DRAM device. Compared with the traditional designs of DRAM devices, since the sidewall 134 of the lower portion 132 of the conductive structure 130 extends beyond the second top surface 122 of the isolation structure 120, the cross-sectional area of the conductive structure 130 adjacent to the first top surface 121 of the isolation structure 120 is increased As a result, the conductive structure 130 is stronger, and the resistance of the conductive structure 130 is reduced. Therefore, the resistance of the storage node using the conductive structure 130 as the electrode declines, which can save the energy consumption of the DRAM device. In some embodiments, a material of the isolation structure 120 may include silicon nitride, and a material of the conductive structure 130 may include tungsten, but the present disclosure is not limited in this regard.

Moreover, the conductive structure 130 of the semiconductor structure 100 further includes an upper portion 133 located on the lower portion 132 of the conductive structure 130 and the first top surface 121 of the isolation structure 120. A distance D1 between the lateral surface 123 of the isolation structure 120 and the sidewall 134 of the lower portion 132 of the conductive structure 130 is less than a width W of the trench 131 surrounded by the upper portion 133 of the conductive structure 130. In addition, the first top surface 121, the lateral surface 123, and the second top surface 122 of the isolation structure 120 define a stepped surface. Furthermore, a sidewall 135 of the upper portion 133 of the conductive structure 130 has a bottom concave surface 136 adjoining the sidewall 134 of the lower portion 132 of the conductive structure 130, and a sidewall 137 of the upper portion 133 of the conductive structure 130 has a bottom concave surface 138 extending to the lateral surface 123 of the isolation structure 120. By the configuration of the trench 131, the bottom concave surface 136, and the bottom concave surface 138 of the conductive structure 130, voids and defects of a material filled in the trench 131 can be prevented in subsequent manufacturing process.

In this embodiment, the semiconductor structure 100 further includes a hard mask layer 140. The hard mask layer 140 is located on the upper portion 133 of the conductive structure 130. A sidewall 141 and a sidewall 142 of the hard mask layer 140 respectively extend to the sidewall 135 and the sidewall 137 of the upper portion 133 of the conductive structure 130. In some embodiments, a material of the hard mask layer 140 may include silicon nitride. The hard mask layer 140 can prevent the underlying conductive structure 130 and the underlying isolation structure 120 from etching.

In the following description, the manufacturing method of the semiconductor structure 100 will be explained.

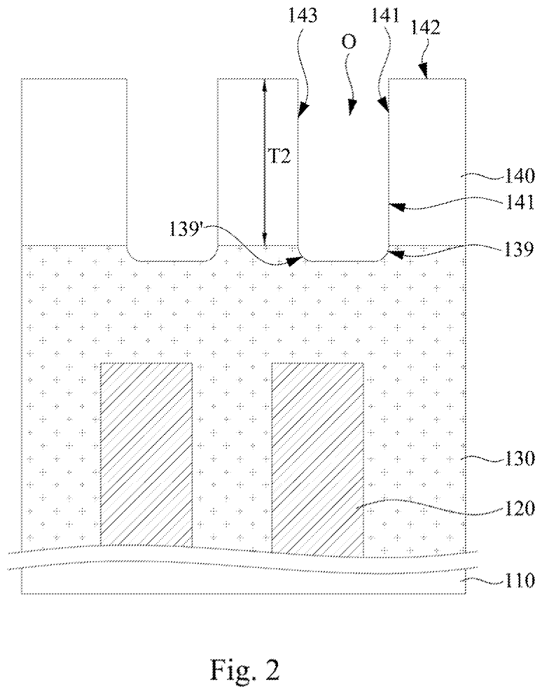

FIGS. 2 to 6 are cross-sectional views at intermediate stages of the manufacturing method of the semiconductor structure 100 of FIG. 1. As shown in FIG. 2, the manufacturing method of the semiconductor structure 100 includes forming the isolation structure 120, the conductive structure 130 surrounding and covering the isolation structure 120, and the hard mask layer 140 on a semiconductor substrate 110 sequentially. The hard mask layer 140 may be patterned to has an opening O to expose the conductive structure 130. In some embodiments, a portion of the exposed conductive structure 130 is removed to form two top concave surfaces 139 and 139′.

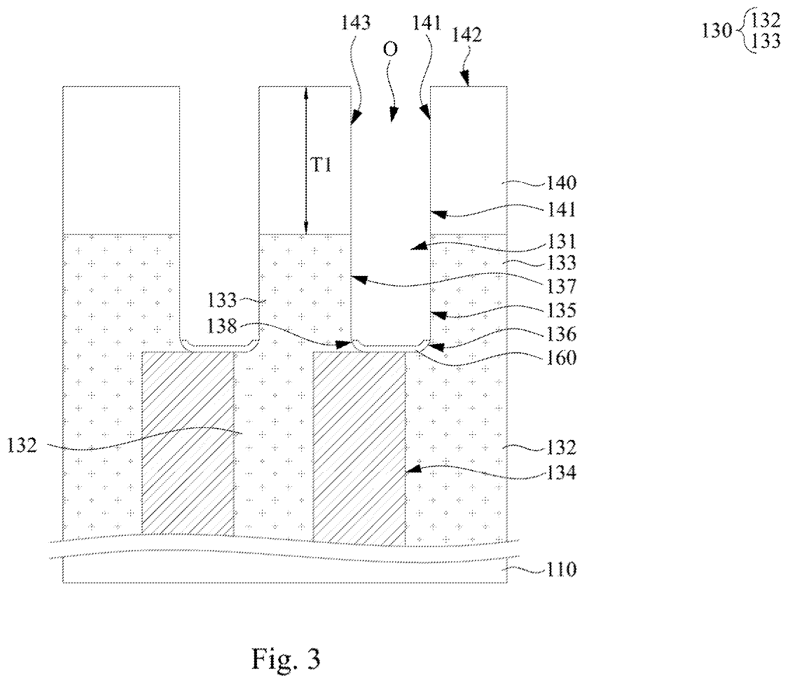

As shown in FIG. 3, thereafter, the exposed conductive structure 130 may be removed to form the trench 131 by dry etching, such that the sidewall 135 and the sidewall 137 of the upper portion 133 of the conductive structure 130 respectively has the bottom concave surface 136 and the bottom concave surface 138. In this embodiment, the material of the conductive structure 130 is tungsten, hence a byproduct layer 160 is produced during the formation of the trench 131 in the conductive structure 130, in which the byproduct layer 160 is located on the isolation structure 120, and in contact with the bottom concave surface 136 and the bottom concave surface 138. In addition, because a material of the byproduct layer 160 may include tungsten, the sidewall 135 and the sidewall 137 of the upper portion 133 of the conductive structure 130 may be electrically connected with each other by the byproduct layer 160. In some embodiments, a thickness T2 (see FIG. 2) of the hard mask layer 140 may be reduced to a thickness T1 after dry etching the exposed conductive structure 130 to form the trench 131.

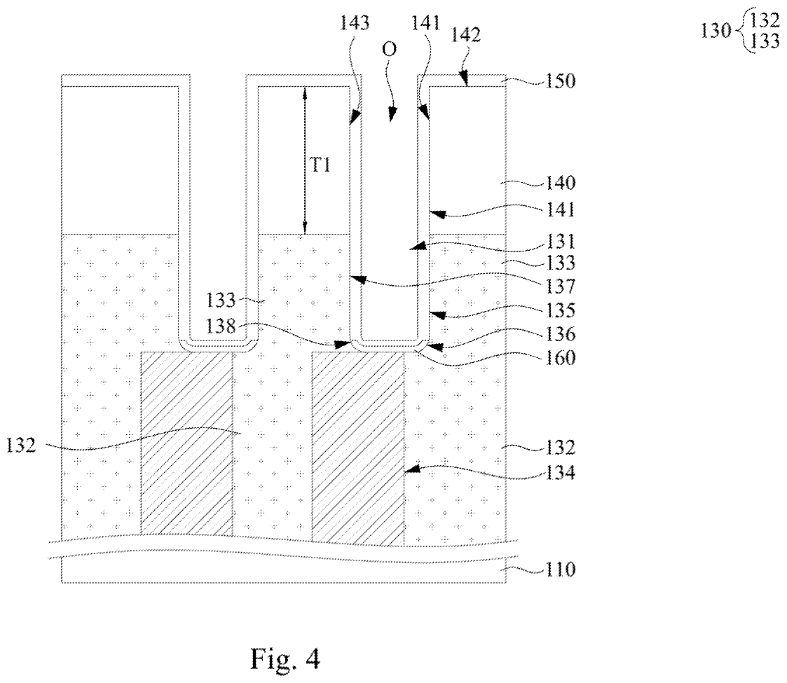

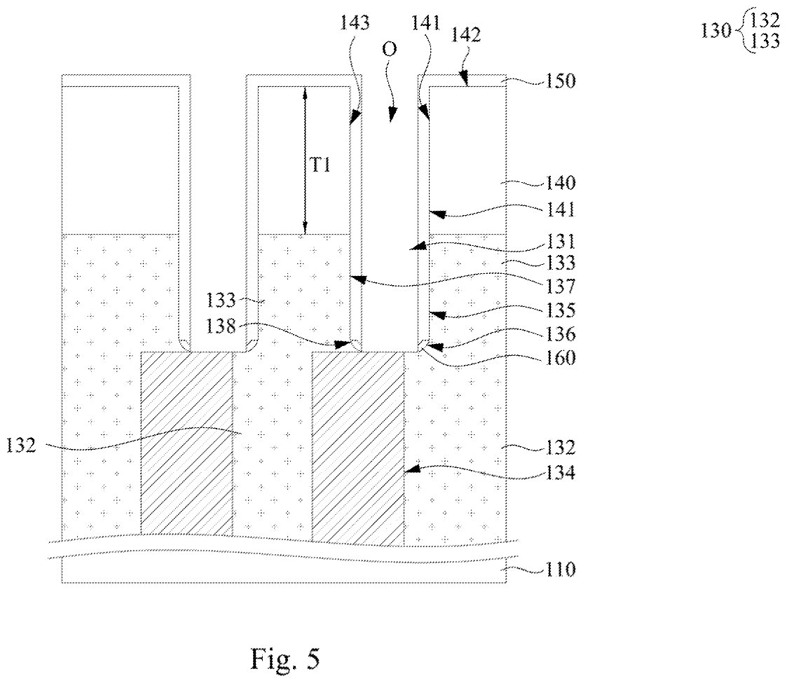

As shown in FIGS. 4 and 5, thereafter, a liner layer 150 may be formed on the isolation structure 120, the sidewall 135 and the sidewall 137 of the upper portion 133 of the conductive structure 130, and the sidewall 141, the sidewall 142, and the top surface 143 of the hard mask layer 140 by atomic layer deposition (ALD). The byproduct layer 160 is located between the isolation structure 120 and the liner layer 150. Afterward, a bottom portion of the liner layer 150 and the byproduct layer 160 on the isolation structure 120 may be removed to expose the isolation structure 120. In some embodiments, a material of the liner layer 150 is oxide (e.g., silicon oxide), but the present disclosure is not limited in this regard.

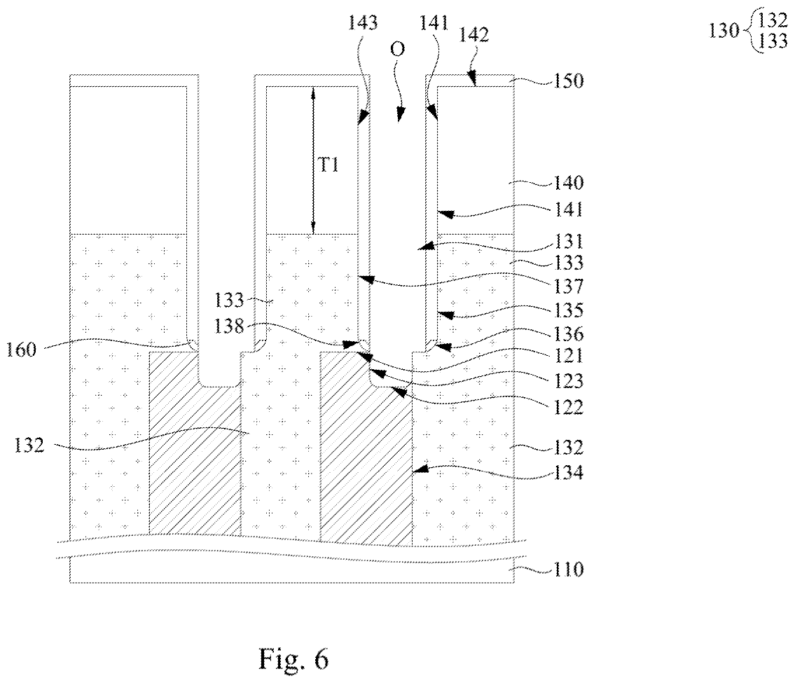

As shown in FIG. 6, thereafter, the exposed isolation structure 120 is removed by reactive-ion etching having selectivity between the isolation structure 120 and each of the liner layer 150 and the conductive structure 130, such that the isolation structure 120 has the first top surface 121 covered by the conductive structure 130, the second top surface 122 lower than the first top surface 121, and the lateral surface 123 adjoining the first top surface 121 and the second top surface 122. The reactive-ion etching may lateral etch the conductive structure 130 with obliquely incident plasma. Since the liner layer 150 is formed on the sidewall 135 and the sidewall 137 of the upper portion 133 of the conductive structure 130, additional byproducts and polymers are not produced on the sidewalls 135 and 137 of the conductive structure 130 during etching the exposed isolation structure 120. Therefore, in some embodiments, the conductive structure 130 can act as an electrode of a SNC structure of a DRAM device to avoid the shorting between electrodes induced by the byproducts and the polymers. In addition, a material of the isolation structure 120 may include silicon nitride, a material of the conductive structure 130 may include tungsten, and a material of the liner layer 150 may include silicon oxide. The reactive-ion etching applied to remove the isolation structure 120 exposed through the trench 131 has selectivity between the silicon nitride and each of the silicon oxide and tungsten.

Afterward, the liner layer 150 is removed to expose the sidewall 135 and the sidewall 137 of the upper portion 133 of the conductive structure 130, and the sidewall 141, the sidewall 142 and the top surface 143 of the hard mask layer 140, thereby obtaining the semiconductor structure 100 of FIG. 1. Thereafter, an insulated structure may be filled in the trench 131. By the configuration of the trench 131 of FIG. 1, the voids and defects of the insulated structure in the trench 131 can be prevented. In some embodiments, a material of the insulated structure may include a nitride insulator (e.g., silicon nitride).

It is to be noted that the connection relationships, the materials, and the advantages of the elements described above will not be repeated in the following description. In the following description, another type of a semiconductor structure will be described.

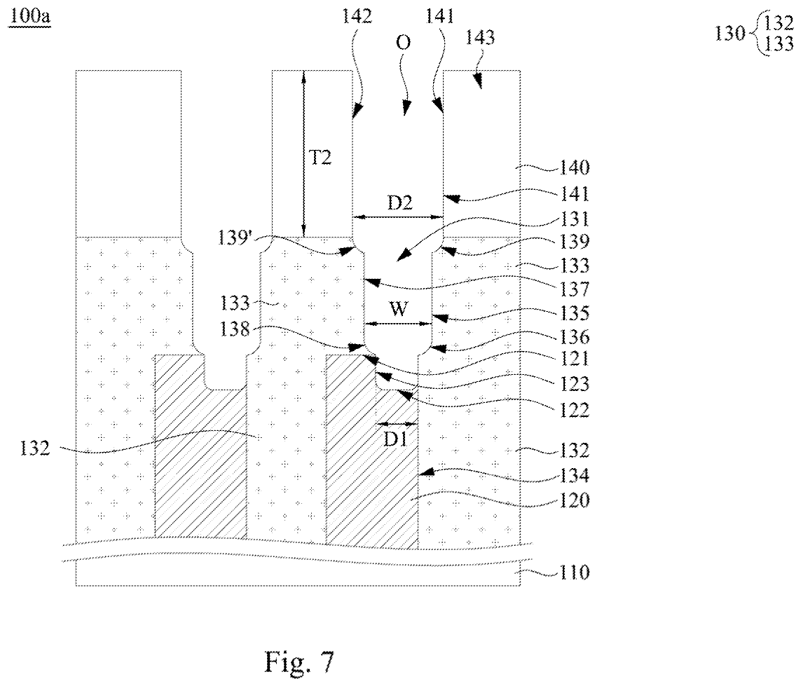

FIG. 7 is a cross-sectional view of a semiconductor structure 100a according to one embodiment of the present disclosure. The semiconductor structure 100a includes the semiconductor substrate 110, the isolation structure 120, the conductive structure 130, and the hard mask layer 140. The difference between this embodiment and the embodiment of FIG. 1 is that the sidewall 135 and the sidewall 137 of the upper portion 133 of the conductive structure 130 respectively has the top concave surface 139 and the top concave surface 139′. The top concave surface 139 of the sidewall 135 of the upper portion 133 of the conductive structure 130 extends to the sidewall 141 of the hard mask layer 140, and the top concave surface 139′ of the sidewall 137 of the upper portion 133 of the conductive structure 130 extends to the sidewall 142 of the hard mask layer 140. The width W of the trench 131 of FIG. 7 is smaller than the width W of the trench 131 of FIG. 1. Therefore, the cross-sectional area of the conductive structure 130 of FIG. 7 is greater than the conductive structure 130 of FIG. 1, and the resistance of the conductive structure 130 may be further reduced. Furthermore, a distance D2 between the sidewall 141 and the sidewall 142 of the hard mask layer 140 is greater than the width W of the trench 131 of FIG. 7.

In the following description, the manufacturing method of the semiconductor structure 100a will be explained.

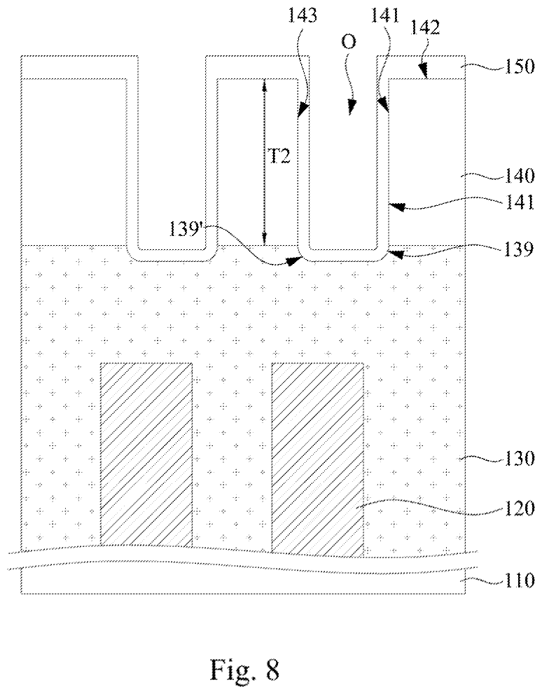

FIGS. 8 to 11 are cross-sectional views at intermediate stages of the manufacturing method of the semiconductor structure 100a of FIG. 7. As shown in FIG. 8, after the structure of FIG. 2 is formed, the liner layer 150 is formed on the sidewall 141, the sidewall 142 and the top surface 143 of the hard mask layer 140, and the exposed conductive structure 130. In addition, the liner layer 150 is in contact with the top concave surfaces 139 and 139′.

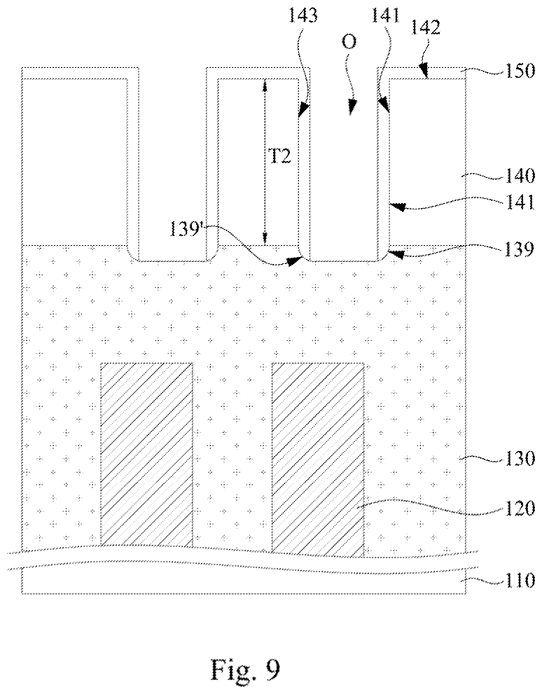

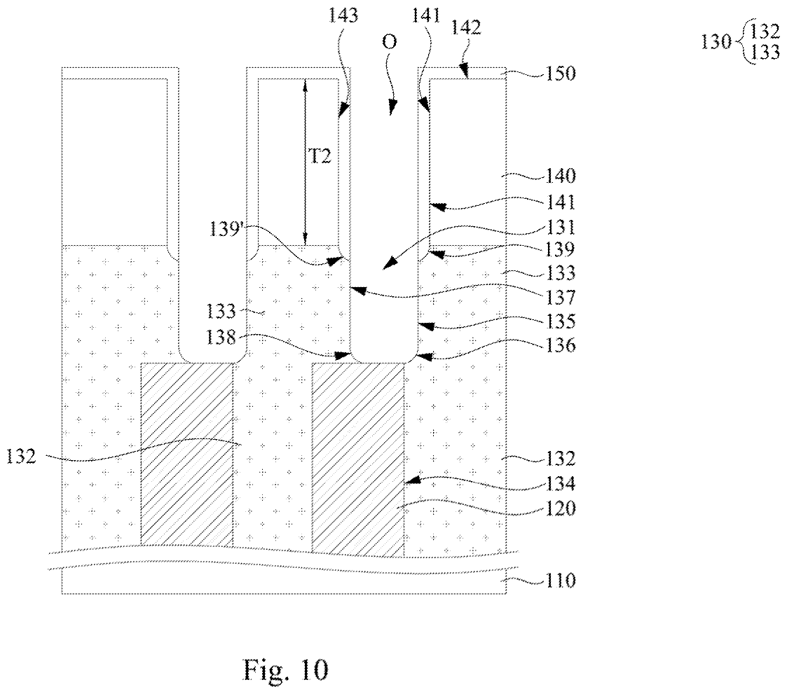

As shown in FIGS. 9 and 10, afterwards, a bottom portion of the liner layer 150 may be removed to expose the conductive structure 130, such that the liner layer 150 covers the sidewall 141, the sidewall 142 and the top surface 143 of the hard mask layer 140. Thereafter, the conductive structure 130 not covered by the hard mask layer 140 and the liner layer 150 may be removed by reactive-ion etching having selectivity between the conductive structure 130 and each of the liner layer 150 and the isolation structure 120, such that the trench 131 can be formed to expose the isolation structure 120. Since the liner layer 150 covers the hard mask layer 140, the thickness T2 of the hard mask layer 140 is maintained after etching the conductive structure 130. Moreover, the thickness T2 of the hard mask layer 140 of FIG. 10 is greater than the thickness T1 of the hard mask layer 140 of FIG. 3. Furthermore, the thickness T2 of the hard mask layer 140 is thick enough to prevent the sidewall 135 and the sidewall 137 of the upper portion 133 of the conductive structure 130 from lateral etching with obliquely incident plasma, and hence avoid the production of byproducts and polymers.

Furthermore, after etching the conductive structure 130 not covered by the hard mask layer 140 and the liner layer 150, the sidewall 135 and the sidewall 137 of the upper portion 133 of the conductive structure 130 respectively has the top concave surface 139 and the top concave surface 139′. The liner layer 150 prevents the top concave surface 139 of the sidewall 135 and the top concave surface 139′ of the sidewall 137 from etching.

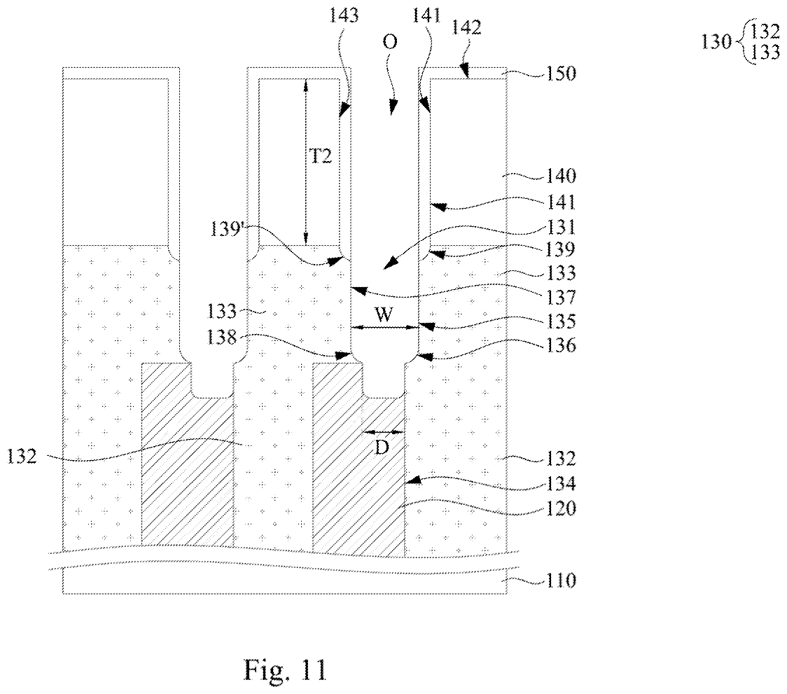

As shown in FIGS. 10 and 11, thereafter, the isolation structure 120 exposed through the trench 131 may be removed. Subsequently, the liner layer 150 may be removed to obtain the semiconductor structure 100a of FIG. 7.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor substrate;
an isolation structure located on the semiconductor substrate, wherein the isolation structure has a first top surface, a second top surface lower than the first top surface, and a lateral surface adjoining the first top surface and the second top surface; and
a conductive structure having a trench extending to the second top surface and the lateral surface of the isolation structure, wherein the conductive structure surrounds the isolation structure and is in contact with the first top surface of the isolation structure, and a sidewall of a lower portion of the conductive structure is in contact with the isolation structure and extends beyond the second top surface of the isolation structure.

2. The semiconductor structure of claim 1, the conductive structure further comprises an upper portion located on the lower portion of the conductive structure and the first top surface of the isolation structure.

3. The semiconductor structure of claim 2, wherein a distance between the lateral surface of the isolation structure and the sidewall of the lower portion of the conductive structure is less than a width of the trench surrounded by the upper portion of the conductive structure.

4. The semiconductor structure of claim 2, wherein a sidewall of the upper portion of the conductive structure has a bottom concave surface adjoining the sidewall of the lower portion of the conductive structure.

5. The semiconductor structure of claim 2, wherein a sidewall of the upper portion of the conductive structure further has a bottom concave surface extending to the lateral surface of the isolation structure.

6. The semiconductor structure of claim 5, further comprising:
a hard mask layer located on the upper portion of the conductive structure.

7. The semiconductor structure of claim 5, wherein the sidewall of the upper portion of the conductive structure further has a top concave surface adjoining a top surface of the upper portion of the conductive structure.

8. The semiconductor structure of claim 7, further comprising:
a hard mask layer located on the upper portion of the conductive structure, wherein the top concave surface of the sidewall of the upper portion of the conductive structure extends to a sidewall of the hard mask layer.

9. The semiconductor structure of claim 1, wherein the first top surface, the lateral surface, and the second top surface of the isolation structure define a stepped surface.

10. A manufacturing method of a semiconductor structure, comprising:
forming an isolation structure, a conductive structure surrounding and covering the isolation structure, and a hard mask layer on a semiconductor substrate sequentially, wherein the hard mask layer has an opening to expose the conductive structure;
removing the exposed conductive structure to form a trench, such that a sidewall of an upper portion of the conductive structure has a bottom concave surface;
forming a liner layer on the isolation structure, the sidewall of the upper portion of the conductive structure, and a sidewall and a top surface of the hard mask layer;
removing a bottom portion of the liner layer to expose the isolation structure;
removing the exposed isolation structure, such that the isolation structure has a first top surface covered by the conductive structure, a second top surface lower than the first top surface, and a lateral surface adjoining the first top surface and the second top surface, and the trench extends to the second top surface and the lateral surface of the isolation structure; and
removing the liner layer to expose the sidewall of the upper portion of the conductive structure, and the sidewall and the top surface of the hard mask layer.

11. The manufacturing method of the semiconductor structure of claim 10, wherein removing the bottom portion of the liner layer to expose the isolation structure further comprises:
removing a byproduct layer on the isolation structure.

12. The manufacturing method of the semiconductor structure of claim 10, wherein removing the exposed isolation structure is performed such that a sidewall of a lower portion of the conductive structure extends beyond the second top surface of the isolation structure.

13. The manufacturing method of the semiconductor structure of claim 10, wherein removing the exposed isolation structure is performed by reactive-ion etching having selectivity between the isolation structure and each of the liner layer and the conductive structure.

14. The manufacturing method of the semiconductor structure of claim 10, wherein forming the liner layer on the isolation structure, the sidewall of the upper portion of the conductive structure, and the sidewall and the top surface of the hard mask layer is performed by atomic layer deposition.

15. A manufacturing method of a semiconductor structure, comprising:
forming an isolation structure, a conductive structure surrounding and covering the isolation structure, and a hard mask layer on a semiconductor substrate sequentially, wherein the hard mask layer has an opening to expose the conductive structure;
forming a liner layer on a sidewall and a top surface of the hard mask layer and the exposed conductive structure;
removing a bottom portion of the liner layer to expose the conductive structure;
removing the conductive structure not covered by the hard mask layer and the liner layer to form a trench and expose the isolation structure, such that a sidewall of an upper portion of the conductive structure has a bottom concave surface;
removing the exposed isolation structure, such that the isolation structure has a first top surface covered by the conductive structure, a second top surface lower than the first top surface, and a lateral surface adjoining the first top surface and the second top surface, and the trench extends to the second top surface and the lateral surface of the isolation structure; and
removing the liner layer to expose the sidewall and the top surface of the hard mask layer.

16. The manufacturing method of the semiconductor structure of claim 15, wherein forming the isolation structure, the conductive structure surrounding and covering the isolation structure, and the hard mask layer on the semiconductor substrate subsequently further comprises:
removing the exposed conductive structure, such that the sidewall of the upper portion of the conductive structure further has a top concave surface extending to the sidewall of the hard mask layer.

17. The manufacturing method of the semiconductor structure of claim 16, wherein forming the liner layer on the sidewall and the top surface of the hard mask layer and the exposed conductive structure is performed such that the liner layer is in contact with the top concave surface of the sidewall of the upper portion of the conductive structure.

18. The manufacturing method of the semiconductor structure of claim 15, wherein removing the exposed isolation structure is performed such that a sidewall of a lower portion of the conductive structure extends beyond the second top surface of the isolation structure.

19. The manufacturing method of the semiconductor structure of claim 15, wherein removing the conductive structure not covered by the hard mask layer and the liner layer to form the trench and expose the isolation structure is performed by reactive-ion etching having selectivity between the conductive structure and each of the liner layer and the isolation structure.

20. The manufacturing method of the semiconductor structure of claim 15, wherein forming the liner layer on the sidewall and the top surface of the hard mask layer and the exposed conductive structure is performed by atomic layer deposition.
